(19) United States
(12) Patent Application Publication
(10) Pub. No.: US 2008/0054451 A1
(43) Pub. Date: Mar. 6, 2008

(54) MULTI-CHIP ASSEMBLY

(76) Inventors: Michael Bauer, Nittendorf (DE); Christian Stuempfl, Schwandorf (DE); Ludwig Heitzer, Regensburg (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/470,511

(22) Filed: Sep. 6, 2006

(51) Int. Cl. H01L 23/34

(52) U.S. Cl. 257/723

(57) ABSTRACT

Chip arrangement and method for producing a chip arrangement

A chip arrangement comprises a first chip with an electrically operable structure on an active surface of the first chip. The first chip is applied on a carrier area in order to make electrical contact with the electrically operable structure via the carrier area. A second chip has a cutout and is arranged on the carrier area, the first chip being arranged in a cavity formed by the cutout and the carrier area.

The invention relates to a chip arrangement for the compact arrangement of a plurality of chips, and to a method for producing such a chip arrangement.

Multichip systems in which a number of chips are arranged and connected to one another in a space-saving manner are known. Thus, by way of example, multichip arrangements have been constructed by stacking a plurality of chips one on top of another directly or with a spacer layer, a so-called interposer, in order to achieve the highest possible packing density. In this case, however, usually either the interposer or the adjacent chip bears directly on the surfaces of the individual chips.

Chips are furthermore known whose active surfaces have regions (surface with functionally relevant, electrically operable structures) which are sensitive to any mechanical contact, as may be the case e.g. with integrated sensor structures, in particular movable elements. The function of such chips would be impaired, or such chips could no longer perform their function, as a result of the direct contact between their active surface and the interposer or the adjacent chip.

In this respect, previous approaches provide for arranging chips of this type in cavity housings which are constructed in a complicated manner with the aid of suitable frames and covers and provide for reliably protecting the active surface against mechanical contact. However, such cavity housings have a high space requirement compared with the size of the sensor chip and are therefore not suitable for a space-saving integrated construction of such a system.

A first aspect provides a chip arrangement. The chip arrangement comprises a first chip with an electrically operable structure on an active surface of the first chip and a carrier area, on which the first chip is applied. A second chip has a cutout and is arranged on the carrier area above the first chip. In this case, the first chip is arranged in a cavity formed by the cutout and the carrier area.

A second aspect provides a further chip arrangement. The latter comprises a first chip, a means for carrying the first chip and a device comprising a second chip and having a cutout shaped in the device by material removal. In this case, the device is arranged such that the first chip is accommodated in the cutout.

Preferred embodiments of the invention are explained in more detail below with reference to the accompanying drawings. In the figures, elements having identical or comparable functions are provided with the same reference symbols. In the figures:

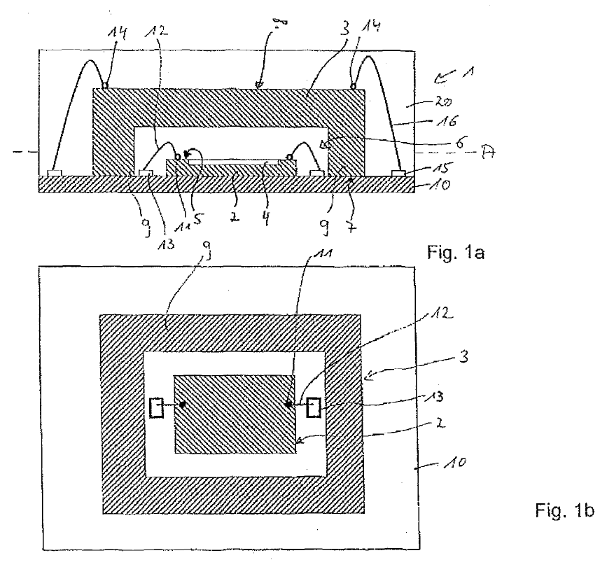

FIG. 1a shows a cross-sectional view of a first embodiment of a chip arrangement;

FIG. 1b shows a sectional view along the sectional line A-A of the embodiment from FIG. 1a;

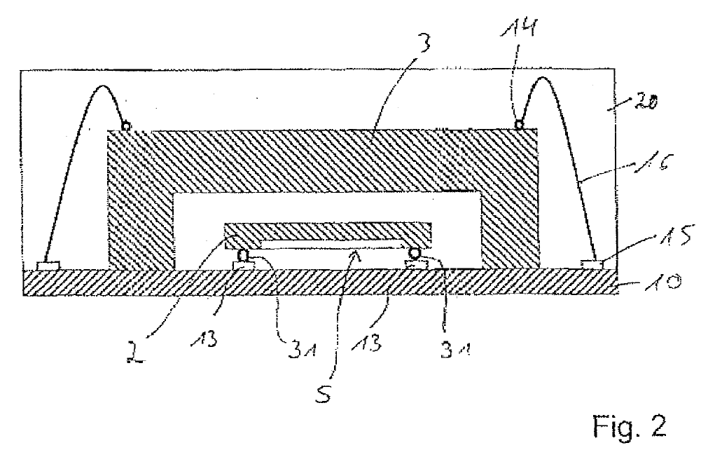

FIG. 2 shows a cross-sectional view of a second embodiment of a chip arrangement;

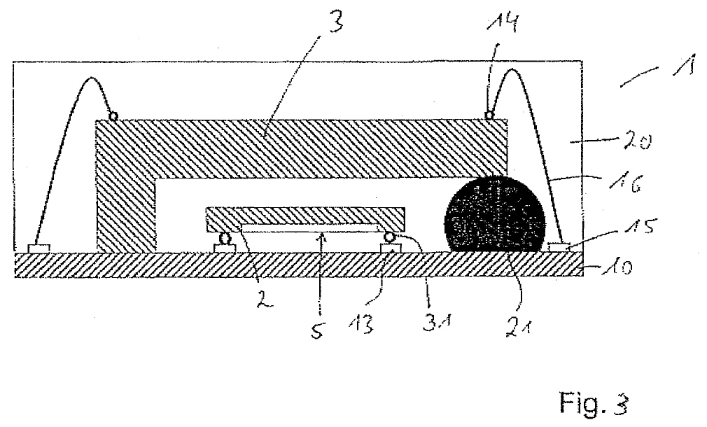

FIG. 3 shows a cross-sectional view of a third embodiment of a chip arrangement; and

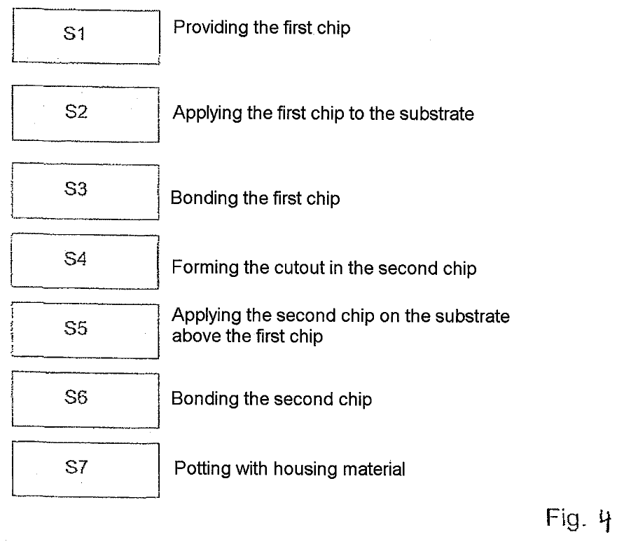

FIG. 4 shows a flowchart for illustrating a method for producing a chip arrangement.

A chip arrangement comprises a first chip, in particular with a first contact structure, via which an electrically operable structure on an active surface of the first chip can be operated. A carrier area, in particular a printed circuit board substrate or a further chip, is furthermore provided, on which the first chip is applied, in order to make electrical contact with the electrically operable structure of the first chip via the carrier area. The chip arrangement furthermore comprises a second chip, which has a cutout and which is arranged on the carrier area above the first chip in such a way that the first chip is accommodated in the cutout, the first chip being arranged in the cavity formed by the cutout and the carrier area in such a way that the active surface is preferably uncovered at least in the region of the electrically operable structure.

The chip arrangement proposed may provide a cavity which is wholly or partly closed off from the surroundings and which is formed with the aid of a cutout formed in a chip and with the aid of a suitable carrier area with which the cutout is covered. In the cavity it is possible to arrange the chip with the active surface which is intended to be protected and which is preferably intended to have no direct mechanical contact with another area or another element, such as e.g. an interposer or a surface of an adjacent chip. Complicated cavity housings can be avoided in this way since the cavity is already formed by the cutout formed in the second chip.

Furthermore, the first chip may have a sensor structure as the electrically operable structure.

The first chip may be formed as a flip-chip component, the first contact structure being formed as a solder bump which is placed onto a second contact structure on the carrier area and is connected thereto. It is also possible for the first chip to be applied on the carrier area by a surface opposite to the active surface, the first contact structure being connected to a second contact structure on the carrier area by means of a bonding wire. Furthermore, the second chip may have a further electrically operable structure on a surface opposite to the cutout, a third contact structure being provided on the surface of the second chip in order to make contact with the further electrically operable structure.

FIG. 1 illustrates a first embodiment of a chip arrangement 1 comprising two chips. The chip arrangement 1 comprises a first chip 2 and a second chip 3. The first chip 2 has electrically operable structures 4 on and in an active surface 5 of the first chip 2. The electrically operable structures 4 may comprise an electronic circuit, actuator structures, sensor structures and the like, such as e.g. acceleration, oscillation, inclination sensor structures or BAW filter structures (bulk acoustic wave). In particular sensor structures and actuator structures are arranged directly at the active surface and often have uncovered movable structural elements which should be able to be moved unimpeded for proper functioning.

The second chip 3 has both larger lateral dimensions and a larger thickness than the first chip 2. The second chip 3 may likewise have electrically operable structures, such as e.g. electronic circuits, at an active surface 8. The second chip 3 has a cutout 6 at a surface 7 opposite to an active surface 8 of the second chip 3, said cutout being introduced into the surface 7 by means of a material removing process step, for example etching. In the plan view in FIG. 1b of a cross-sectional view of the chip arrangement 1 along a sectional line A-A, it is evident that in the embodiment shown, the cutout 6 is formed in the inner part of the second chip 3 with respect to the active surface 8, so that edge regions 9 remain at the edges of the second chip 3.

In the embodiment shown, the first chip 2 is applied to a carrier area of a substrate 10 by a surface opposite to its active surface 5. The first chip 2 is mechanically fixed on the carrier area of the substrate 10 e.g. by means of a suitable adhesive bonding method. Situated on the active surface 5 of the first chip 2 are first contact structures 11, which are connected to second contact structures 13 on the surface of the substrate 10 by means of a bonding wire 12. For the sake of simplicity, only two connections of this type are shown in the illustration shown. The number of first contact structures 11, second contact structures 13 and bonding wires 12 is typically greater than two.

The second chip 3 is arranged with its cutout 6 above the first chip 2 in such a way that the latter is located in the cutout 6, the edge regions 9 as far as possible lying outside the region defined by the first chip 2 and the region defined by the contact-connections with the bonding wires 12. The second chip 3 is likewise mechanically fixed on the carrier area of the substrate 10, for example by adhesive bonding, in order to establish its position on the substrate 10. The depth of the cutout 6 is chosen such that the first chip 2 including its bonding connections with the aid of the bonding wires 12 can be accommodated therein without the bonding wires 12 touching a surface of the second chip 3, that is to say that the depth of the cutout is greater than the thickness of the first chip 2.

The active surface 8 of the second chip 3 may have third contact structures 14, which are connected to fourth contact structures 15, e.g. in the form of contact areas, on the substrate 10 by means of further bonding wires 16 or other suitable connections. After the construction of the chip arrangement 1, the first and second chips 2, 3 on the substrate 10 may be potted with a suitable insulating housing material 20 in order to completely seal and thereby protect the chip arrangement 1 from the external surroundings.

The substrate 10 may comprise conductive paths which are electrically coupled to the second and fourth contact structures 13, 15 and serve for signal distribution and/or signal linking to external components. By way of example, the substrate may be a printed circuit board substrate. In accordance with a further embodiment (not shown), the driving of the electrically operable structures both in the first and/or in the second chip 2, 3 may also be performed contactlessly, e.g. inductively with the aid of an induction coil and the like.

FIG. 2 illustrates a further embodiment of a chip arrangement, which differs from the embodiment of the chip arrangement of FIGS. 1a and 1b by virtue of the fact that the first chip 2 is formed as a flip-chip having solder bumps 31 as first contact structures 11 on its active surface 5. The flip-chip is arranged on the substrate 10 in such a way that the active surface 5 is opposite the carrier area of the substrate 10. The solder bumps 31 are placed onto the substrate 10 in such a way that they make contact with second contact structures 13 situated thereon, said second contact structures being formed e.g. as contact areas. Solder bumps 31 and contact areas 13 are connected to one another in a suitable manner, e.g. with the aid of a reflow process. As a result of the electrical and mechanical connection of the molten solder bumps 31 to the second contact structures 13, it is possible, if appropriate, to dispense with a further mechanical fixing of the first chip 2.

Due to the height of the solder bumps 31, the active surface 5 of the first chip 2 remains spaced apart from the surface of the substrate 10 even after contact-connection. Mechanical contact with the active surface of the first chip 2 is thereby avoided, with the result that the function of mechanical movable structures situated there is not impaired by possible contact with a further surface, such as e.g. the surface of the substrate 10.

In the case of the embodiment shown in FIG. 2, too, it is provided that the cutout 6 is completely surrounded by edge regions 9 of the second chip. However, it is also possible as an alternative, as illustrated in FIG. 3, to provide the cutout 6 at an edge region of the second chip 3 in such a way that no edge region 9 remains at least one side, so that the cavity formed by the second chip 3 and the substrate 10 is open to the surroundings at one side. This may make it possible, after the construction of the chip arrangement, to fill the cavity with a suitable means, such as e.g. a liquid or a gas, in order to set a defined state for the sensor structures, such as e.g. for setting a damping for oscillatory-movable structural elements. After the possible filling of the cavity that is open at least on one side, the cavity may be sealed by a suitable closure material 21 after being filled with the desired gas or with the desired liquid. The closure material 21 used may be, for example, a sealing adhesive that is applied or introduced between the substrate 10 and the second chip 3 in the region of the opening of the cavity formed by the cutout 6 and is cured or solidified without it coming into contact with the active surface 5 of the first chip 2. The means filled into the cavity is enclosed in the cavity in this way. It goes without saying that the cavity may also be sealed by the subsequent potting with the housing material 20.

In a method for producing a chip arrangement, firstly a first chip may be provided, in particular having a first contact structure, via which an electrically operable structure on an active surface of the first chip can be operated. The first chip is applied to a carrier area, it being possible for electrical contact to be made with the electrically operable structure of the first chip via the carrier area. A second chip or a component containing a second chip is provided with a cutout in order to accommodate at least the first chip. The second chip or the component may then be arranged on the carrier area above the first chip in such a way that the first chip is accommodated in the cutout and is arranged in the cavity formed by the cutout and the carrier area in such a way that the active surface of the first chip is uncovered at least in the region of the electrically operable structure.

FIG. 4 illustrates a flowchart for illustrating the method for producing a chip arrangement 1. Step S1 involves providing a first chip 2 having a first contact structure 11 in order to operate an electrically operable structure, such as e.g. a sensor structure, on an active surface.

In step S2, the first chip 2 is applied to a substrate 10, it being possible for electrical contact to be made with the electrically operable structure of the first chip 2 via the substrate 10.

For this purpose, in step S3, the first contact structures 11 on the active surface of the first chip 2 are connected to second contact structures 13, such as e.g. contact areas, by means of a bonding wire 12. As an alternative, the first chip 2 may also be formed as a flip-chip, the first contact structures being formed as solder bumps 31 on the active surface 5, which are placed onto the corresponding second contact structures 13 and are melted e.g. by means of a reflow process, so that they join together with the second contact structures 13.

Furthermore, in step S4, a second chip is provided with a cutout 6, preferably at a surface opposite to an active surface with further electrically operable structures. The cutout may be introduced into the chip material (e.g. silicon) by means of an etching process. The cutout 6 has a depth which suffices to accommodate the first chip 2 applied on the substrate 10 including its contact-connection elements, such as e.g. the bonding wires 12 and the like, without the contact-connection elements (contact structures and bonding wires) coming into contact with a surface of the first chip 2 (e.g. the bottom of the cutout 6) in such a way as to create a short circuit or an undesirable electrical connection.

In step S5, the second chip 3 is arranged with its cutout 6 above the first chip 2 and is mechanically connected to the substrate 10, e.g. with the aid of an adhesive. A closed or partly accessible cavity is therefore created by means of the cutout and the substrate, said cavity being closed off from the surroundings, so that the active surface 5 of the first chip 2 is protected against external influences.

The second chip 3 has third contact structures 14, which are connected by means of further bonding wires 16 to fourth contact structures 15, which are arranged on the surface of the substrate 10, by means of bonding wires 16 with the aid of a bonding method in step S6.

Afterwards, in step S7, the chip arrangement including the further bonding wires 16 is encapsulated in a housing material 20 and a component that is completely protected from the surroundings is thus created.

The second chip 3 may also be accommodated in a device which is arranged instead of the second chip 3 in FIGS. 1 and 3 and has a cutout formed by material removal for accommodating the first chip 2.

1.-25. (canceled)

26. A chip arrangement, comprising:
a first chip with an electrically operable structure on an active surface of the first chip;
a carrier area, on which the first chip is disposed; and
a second chip forming at least a partial enclosure sized to accommodate the first chip, wherein the second chip is arranged on the carrier area over the first chip, the first chip being disposed in a cavity formed by the enclosure and the carrier area.

27. The chip arrangement according to claim 26, wherein the active surface is uncovered at least in a region of the electrically operable structure.

28. The chip arrangement according to claim 26, wherein the electrically operable structure comprises at least one of a sensor structure and an actuator structure.

29. The chip arrangement according to claim 26, wherein the carrier area is one of a printed circuit board substrate and a third chip.

30. The chip arrangement according to claim 26, wherein the active surface of the first chip faces the carrier area.

31. The chip arrangement according to claim 26, wherein the carrier area is connected to the first chip by a solder bump.

32. The chip arrangement according to claim 26, wherein the active surface of the first chip is separated from the carrier area by a gap.

33. The chip arrangement according to claim 26, wherein the carrier area is connected to the first chip by a bonding wire.

34. The chip arrangement according to claim 26, wherein the second chip comprises a further electrically operable structure on a surface.

35. The chip arrangement according to claim 34, wherein the further electrically operable structure is connected to the carrier area by a further bonding wire.

36. The chip arrangement according to claim 26, wherein the enclosure is open at least one side of the second chip.

37. The chip arrangement according to claim 26, wherein the at least one open side is sealed off by a closure material.

38. A chip arrangement, comprising:
a first chip;
a means for carrying the first chip; and
a device comprising a second chip and having a cutout formed in the device by material removal; wherein the device is arranged in such a way that the first chip is accommodated in the cutout.

39. The chip arrangement according to claim 38, wherein the first chip comprises an electrically operable structure on an active surface, and the first chip is arranged in the cutout of the device in such a way that the electrically operable structure is not in contact with the device.

40. The chip arrangement according to claim 38, wherein the first chip is disposed as a flip-chip component on the means for carrying the first chip.

41. The chip arrangement according to claim 38, wherein the second chip comprises a further electrically operable structure on a surface opposite to the cutout.

42. A method for producing a chip arrangement, comprising
providing a first chip having an electrically operable structure on an active surface of the first chip;
applying the first chip to a carrier area;
providing a second chip forming at least a partial enclosure sized to accommodate the first chip; and
arranging the second chip on the carrier area above the first chip in such a way that the first chip is arranged in a cavity formed by the enclosure and the carrier area.

43. The method according to claim 42, wherein the active surface of the first chip is uncovered at least in the region of the electrically operable structure.

44. The method according to claim 42, wherein the active surface of the first chip faces the carrier area.

45. The method according to claim 42, wherein the carrier area is connected to the first chip by a solder bump.

46. The method according to claim 42, wherein the active surface of the first chip is separated from the carrier area by a gap.

47. The method according to claim 42, wherein the carrier area is connected to the first chip by a bonding wire.

48. The method according to claim 42, wherein the second chip comprises a further electrically operable structure on a surface opposite to the enclosure.

49. The method according to claim 48, wherein the further electrically operable structure is connected to the carrier area by a further bonding wire.

50. The method according to claim 42, wherein the enclosure in the second chip is formed by means of an etching process.
